(19) United States
(12) Patent Application Publication
(10) Pub. No.: US 2004/0067447 A1
(43) Pub. Date: Apr. 8, 2004

(54) Method for making a multilevel circuitry comprising conductor tracks and microvias

(76) Inventors: Robert Cassat, Ternay (FR); Vincent Lorentz, Bergholtz (FR)

Correspondence Address: BURNS DOANE SWECKER & MATHIS L L P, POST OFFICE BOX 1404, ALEXANDRIA, VA, 22313-1404, US

(21) Appl. No.: 10/451,913

(22) PCT Filed: Dec. 24, 2001
(86) PCT No.: PCT/FR01/04150

(30) Foreign Application Priority Data
Dec. 29, 2000 (FR) 00/17249

(51) Int. Cl. G03F 7/16; C25D 5/02; H01L 21/288; G03F 7/20; H05K 1/11; H01R 12/04; G03F 7/40; H01L 21/445; H05K 3/00

(52) U.S. Cl. 430/312; 430/315; 205/125; 205/123; 430/318; 174/262

(57) ABSTRACT

The invention concerns a method for making an multilevel interconnection circuitry comprising conductor tracks and micro-vias. The method for producing at least one of the levels comprises the following steps: a) on a substrate including at its surface metallizable and/or potentially metallizable parts (102), forming a first insulating photosensitive resin layer (103) comprising a compound capable of inducing subsequent metallization; b) exposing and revealing the first layer (103) so as to selectively uncover the metallizable and/or potentially metallizable parts (102) of the substrate; c) forming, by metallization, metal conductor tracks (111) and micro-vias (110) at the surface of the first insulating photosensitive resin layer (113) and of the parts uncovered during step b), by providing a second photosensitive resin layer (105) forming a selective protection, the second photosensitive resin layer (105) being eliminated.

The invention relates to an improved process for producing a multilevel interconnect circuitry comprising conducting tracks and microvias and possibly pads.

Within the context of the invention, the term “microvias” is understood to mean microconnections passing right through the thickness of a dielectric layer.

Within the electronics field, there is a trend towards optimum product miniaturization and towards increasing performance in terms of speed. These trends are accentuated by the growing use of surface-mounted components such as BGA, CGA, CSP or other flip-chip components.

Integration densification is desirable in three dimensions: both in an axial direction by successively stacking ever thinner dielectric/copper layers, in order to obtain a multilayer, and in the plane perpendicular to this direction by bringing ever finer tracks and pads closer together.

The process of the invention meets these requirements by producing a “fine line” circuitry characterized by track and intertrack widths of less than 100 μm and hole or via diameters of less than 100 μm.

This process also ensures excellent adhesion of the metal layers to the dielectric substrate and limits any imprecision due to the successive stacking of the layers.

The process of the invention is furthermore economically advantageous in so far as it involves a small number of steps.

According to a first of its aspects, the invention provides a process for forming conducting tracks and microvias in a dielectric covering a first circuitry level or a first metallized layer, without damage to the said first circuitry level or the said first metallized layer.

The process described in U.S. Pat. No. 5,260,170 teaches how to fabricate circuitries comprising conducting microvias. This process comprises the following steps:

1. applying a first layer of photosensitive resin, containing an electrochemical metallization catalyst, to a substrate;

2. irradiating and developing the said first layer so as to expose certain parts of the substrate;

3. applying a second layer of photosensitive resin, not containing a metallization catalyst;

4. irradiating and developing the said second layer so as to expose certain parts of the first layer and of the substrate;

5. metallizing electrochemically.

Steps 3, 4, 5 are used to form tracks and microvias, the second layer of photosensitive resin forming selective protection. This layer is not removed.

The process may be repeated several times so as to obtain multilayer circuitries, the final surface obtained serving as substrate.

The circuitries obtained according to the process described above suffer from poor planarity, which is to the detriment of their precision. This drawback is due to swelling phenomena in the photosensitive resin in contact with solutions used for various treatments, such as the activation of the catalyst or the metallization. It may also be due to too great a superposition of layers.

The invention provides an improved process for fabricating a circuitry, making it possible in particular to achieve better planarity. The process also has the advantage of being more reliable, by reducing the amount of circuitry that would be off-specification as a result of imprecisions in the superposition of the layers and in the positioning of the microvias.

For this purpose, the invention provides a process for fabricating a multilevel interconnect circuitry comprising metal tracks and microvias, comprising the following steps for producing at least one level:

a) forming, on a substrate having metallizable and/or potentially metallizable parts on its surface, a first layer of insulating photosensitive resin containing a compound capable of inducing subsequent metallization;

b) irradiating and developing the first layer so as to selectively expose metallizable and/or potentially metallizable parts of the substrate;

c) forming, by metallization, metal tracks and microvias on the surface of the first layer of insulating photosensitive resin and of the parts exposed in step b), with the use of a second layer of photosensitive resin forming selective protection; characterized in that

the process comprises, for producing the level in question, a step during which the second layer of photosensitive resin is removed.

The circuitries are obtained by forming layers and/or deposits of layers of materials of different types on defined parts. Thus, metal tracks, metal microvias and, possibly, metal pads, separated in places and supported by layers of an insulating material, are obtained.

The tracks, microvias and pads form an interconnect circuitry.

The tracks are circuitry parts positioned on the surface of an insulating material. They are generally in the form of lines of small thickness.

The circuitries according to the invention comprise several circuitry levels.

Each circuitry level corresponds to a combination of tracks on the surface of an insulating material. The circuitry levels are therefore separated by a layer of insulating material, with metal connection areas between the levels. These metal connections between two or more levels are called microvias. Such structures and such terms are known to those skilled in the art.

The manufacture of the circuitry, for at least one of the levels, comprises steps a), b) and c), with removal of the second layer for this level.

According to the invention, the layers of insulating material separating the circuitry levels consist of insulating photosensitive resin containing a compound capable of inducing subsequent metallization. This layer is called the “first layer”. The microvias providing metal connection between the levels through this layer are positioned at points where parts of the first layer have been removed by being irradiated and developed. They are often referred to as “photovias”.

During step a), a first layer of photosensitive resin is formed on the surface of a substrate having metallizable and/or potentially metallizable parts.

The expression “potentially metallizable surface” is understood to mean a surface part which cannot be directly metallized electrolytically and/or electrochemically, but which can be metallized after it has undergone a suitable treatment. For example, it may be a surface part of an insulating, photosensitive or non-photosensitive, resin containing a compound capable of inducing subsequent metallization. In particular, it may be a layer part having served as a first layer of insulating photosensitive resin during the production of a lower level.

The expression “metallizable surface part” is understood to mean a surface which can be directly metallized electrolytically and/or electrochemically. For example, it may be a metal part, for example tracks, pads or microvias on the surface of the substrate.

The tracks and microvias are formed by metallization on the surface of the first layer of photosensitive resin and of those parts of the substrate which are exposed during step b). The metal parts formed on the surface of the parts exposed during step b) correspond to the microvias.

To form the tracks and microvias, selective protection is obtained by the use of a second layer of photosensitive resin. The processes for forming metal interconnects with selective protection by a layer of photosensitive resin are known to those skilled in the art. In particular, mention may be made of the pattern-type processes and the panel-type processes. In the process according to the invention, the metallization on the parts of the first layer of photosensitive resin is made possible by the compound, contained in the said resin, capable of inducing subsequent metallization and possibly by a suitable treatment prior to the metallization.

According to the invention, the layer of photosensitive resin (second layer of photosensitive resin) used to form the selective protection is removed during the process.

Removing the second layer of photosensitive resin, for an intermediate circuitry level, improves the planarity. The expression “intermediate level” is understood to mean a level which is not the last one and will be used as lower level when forming an upper layer. It also leaves available, on certain parts, a surface of insulating photosensitive resin containing a compound capable of inducing subsequent metallization. Should there be any imprecision when fabricating an upper circuitry level or when positioning the microvias, the metallization and the formation of a contact remain possible with very good cohesion, something which is not the case if the second layer of photosensitive resin is not removed.

The substrate may be a lower circuitry level produced according to the process of the invention, or according to another process. If the substrate is a lower circuitry level produced according to the process of the invention, the metallizable parts are circuitry parts of the lower level, in particular of the tracks and/or microvias, and the potentially metallizable parts are non-metallized parts of the first layer of insulating photosensitive resin used when producing the lower level.

The substrate may also be a printed circuit having one or more levels on a rigid or flexible support, possibly with conducting vias. As regards the supports, this may, for example, be an injection-moulded insulating material or a composite material conventional in the field of printed circuits. Mention may be made, for example, of epoxy/glass-fibre supports. It may be a dielectric material comprising a web of non-woven fibres or a paper, impregnated with dielectric resin. The presence of the web or paper ensures good uniformity of the thermal expansion coefficients (TECs).

Particularly advantageously, the support is a web consisting of non-woven aramid (a commercial aromatic polyamide) fibres preimpregnated with an epoxy resin, with a polyimide resin or with a blend of these resins. Better still, these aramid fibres (which are preferably meta-aramid fibres, para-aramid fibres or a mixture of such fibres) are preimpregnated with a functionalized polyamideimide (functionalized with heat-crosslinkable chemical units). This functionalization may be achieved with double bonds or with maleimide groups such as those defined in patent EP 0 336 856 or U.S. Pat. No. 4,927,900. Advantageously, the web comprises 35 to 60% by weight, preferably from 44 to 55% by weight and better still from 40 to 50% by weight, for example 47% by weight, of dielectric resin.

By way of example, the thickness of the web varies between 10 and 70 μm, preferably between 15 and 50 μm and better still between 20 and 40 μm.

In general, its grammage varies between 10 and 50 g/m² and better still between 15 and 40 g/m².

It should be pointed out that the circuitries obtained by the process according to the invention may be produced on one or both sides.

During step a), a first layer of insulating photosensitive resin is formed on a substrate.

The first layer of insulating photosensitive resin contains a compound capable of inducing subsequent metallization. Preferably this comprises particles of a metal oxide. The metal oxide is chosen from Cu, Co, Cr, Ni, Pb, Sb and Sn oxides and mixtures thereof. Most particularly, cuprous oxide Cu₂O is preferred. The resin may also contain inert non-conducting fillers.

With regard to the metal oxide, this must be in the form of small-sized particles; the particle size is generally between 0.1 and 5 μm.

The resin may be chosen from negative or positive photosensitive resins. Advantageously, it is applied to the substrate or to the lower circuitry level in the form of a solution in a solvent and/or in the form of an uncrosslinked stage-A fluid. By way of example of a resin, mention may be made of the PROBIMER range sold by Vantico. The compound capable of inducing subsequent metallization is in principle introduced into these resins before the layer is formed.

The thickness of the resin is such that there is sufficient insulation between two layers of conducting material. Advantageously, it is less than 100 μm, for example between 10 and 20 μm, preferably between 20 and 40 μm. The dielectric permittivity of the layer is advantageously less than 5.

The compound capable of inducing subsequent metallization is used to produce a metallization after a treatment, for example a treatment resulting in the formation of a sublayer. Treatments that can be used will be described below.

During step b), the first layer of resin is irradiated and then developed. Depending on the nature of the resin—positive or negative—the parts removed during the developing operation are the irradiated or unirradiated parts.

The operations of irradiating and of developing a layer of photosensitive resin, so as to expose parts of subjacent layers, are known to those skilled in the art. Two techniques known from the art are perfectly suitable.

The first consists in irradiating the layer of resin using a predetermined mask. The second technique is the so-called LDI (Laser Direct Imaging) technique for direct exposure of the photosensitive resin.

This technique is advantageous from the economic standpoint since it does not require the use of a mask.

According to this second technique, the photosensitive resin is selectively irradiated, pixel by pixel, by a laser beam scanning the surface of the dielectric coated with photosensitive resin.

The solubilizable parts of the resin are then removed in the same way as in the conventional technique using positive and negative photosensitive resins.

To implement this second technique, two types of laser are, for example, suitable: a laser operating in the infrared (thermal LDI) and a UV laser operating in the 330-370 nm wavelength range (UV-LDI).

Step c) itself comprises several steps. There are several ways of implementing step c), corresponding to different sequences of steps. Three sequences corresponding to different particular methods of implementation will be explained below.

During step c), a second layer of photosensitive resin is used. Advantageously, the second layer does not contain a compound capable of inducing subsequent metallization.

The resin for the second layer may be chosen from positive or negative photosensitive resins. The layer may be formed by application in the form of a solution in a solvent and/or in the form of an uncrosslinked stage-A fluid. By way of example of a resin, mention may be made of the PROBIMER range sold by Vantico.

The layers of photosensitive resins, particularly the first one, may include, where appropriate, other non-conducting and inert compounds, such as pulverulent mineral fillers. These may be, for example, calcium carbonate particles. The presence of such fillers, particularly in the first layer, may improve the cohesion of the metal layers formed and improve their adhesion. The particle size of the fillers is chosen so as to be compatible with the process of applying the resins.

During step c), the second layer is irradiated and then developed so as to expose certain parts of the first layer and/or of the substrate and/or of certain metal layer parts formed before the second layer has been formed. The nature of the exposed parts may vary depending on the particular methods of implementation that are used. Methods of implementation will be described below. For example, in the case of a first method of implementation, certain parts of the first layer and the parts exposed during step b) of the substrate are exposed and, in the case of other methods of implementation, certain parts of a metal layer formed over the entire surface of the first layer are exposed. Depending on the nature of the resin—positive or negative—the parts removed during the development operation are the irradiated or unirradiated parts.

The irradiation and development of the second layer of photosensitive resin may be carried out using the methods described for the first layer of photosensitive resin.

The tracks and microvias are formed by metallization over all or part of surfaces not protected by the second layer of photosensitive resin, either before the latter has been applied or after certain parts of the latter have been removed. The metallization may be carried out electrochemically (electrolessly) and/or electrochemically (with a current). The latter process is more particularly preferred as it is more rapid. In addition, it may be carried out in acid medium, thereby preventing the photosensitive layers from swelling and thus improving the positioning precision for the various irradiation and development steps and improving the reliability and longevity of the circuitries. For electrolytic metallization it is advantageous to operate with increasing current. The metal is preferably copper.

Electrochemical (electroless) metallization is a known technique, which is described in “Encyclopedia of Polymer Science and Technology, 1968, Vol. 8, 658-61”.

Likewise, the electrolytic metallization, (with a current) is a conventional technique also described in “Encyclopedia of Polymer Science and Technology, 1968, Vol. 8, pp. 661-63”.

According to a particularly preferred method of implementing the invention, the metallization, whether electrochemical or electrolytic, is continued until a metal layer having a thickness of at least 5 μm, preferably a thickness of between 10 and 20 μm, is obtained.

Step c) comprises, advantageously before the metallization, a step of forming a sublayer capable of being metallized. Such a sublayer is formed on the surface of the first layer of photosensitive resin, or on the surface of exposed parts of the first layer with selective protection of the other parts by the second layer. Depending on the case, the sublayers formed are continuous or discontinuous and may or may not be directly suitable for electrolytic metallization. On the other hand, they are always suitable for electrochemical metallization. In this case, the electrochemical deposition of metal is catalysed by the sublayer, and the metallization is equivalent to those using palladium or platinum.

Two methods of production for obtaining a sublayer capable of being metallized are preferred.

According to a first method of producing the sublayer, the compound capable of inducing subsequent metallization is chosen from the abovementioned metal oxides and the sublayer is formed by bringing the first layer or exposed parts of the first layer into contact with a solution of a salt of a noble metal capable of being reduced by oxide particles.

During this step, other layers may be brought into contact with the solution. The latter has no useful action on these other layers. Thus, a continuous sublayer of noble metal is formed on the exposed surface of the first layer. The surface resistivity of the sublayer is between 10⁶ and 10³ Ω/□. It is preferably less than 10³ Ω/□. This allows electrochemical metallization to be carried out, preferably with increasing current. It should be pointed out by way of indication that the cohesion of the sublayer improves as the concentration of oxide particles increases.

As preferred solutions of noble metal salts, mention may be made of Au, Ag, Rh, Pd, Cs, Ir and Pt salt solutions with a counterion chosen from Cl⁻, NO⁻₃ and CH₃COO⁻. The contacting process may be carried out by dipping into the solution, by spraying or by the passage of a roller. The solution of noble metal salt is in general acidic, with a pH of between 0.5 and 3.5, preferably between 1.5 and 2.5. The pH may be controlled by adding acid. This treatment in acid medium furthermore makes it possible to limit the swelling of the resin layers, which takes place in basic medium. Excellent definition and excellent planarity are therefore obtained using this first method of producing the circuitries. It should be mentioned that the treatment with an acid solution of noble metal salts may be preceded by rinsing with an acid solution, for example with acetic acid, if the first layer of photosensitive resin contains calcium carbonate particles. This rinsing makes it possible to increase the roughness of the surface, the calcium carbonate particles present on the surface being dissolved, and thus to improve the adhesion of the metal films.

For the first method of forming a sublayer, the metal oxide particles are preferably chosen from MnO, NiO, Cu₂O and SnO and are preferably contained in the first layer in an amount of 2.5-90% by weight, even more preferably in an amount of 10 to 30%. The preferred metal oxide is cuprous oxide Cu₂O. Advantageously, the solution contains at least 10⁻⁵ mol/l, preferably between 0.0005 and 0.005 mol/l, of noble metal salt. A continuous sublayer of noble metal having a thickness of less than 1 μm is obtained. The sublayer obtained exhibits excellent uniformity, thereby improving the quality of the connections obtained after metallization. By way of salts than can be used, mention may be made of AuBr₃ (HAuBr₄), AuCl₃ (HAuCl₄) or Au₂Cl₆, silver acetate, silver benzoate, AgBrO₃, AgClO₄, AgOCN, AgNO₃, Ag₂SO₄, RuCl₄.5H₂O, RhCl₃.H₂O, Rh(NO₃)₂.2H₂O, Rh₂(SO₄)₃.4H₂O, Pd(CH₃COO)₂, Rh₂(SO₄)₃.12H₂O, Rh₂(SO₄)₃.15H₂O, PdCl₂, PdCl₂.2H₂O, PdSO₄, PdSO₄.2H₂O, Pd(CH₃COO)₂, OsCl₄, OsCl₃, OsCl₃.3H₂O, 0sl₄, IrBr₃.4H₂O, IrCl₂, IrCl₄, IrO₂, PtBr₄, H₂PtCl₆ 6H₂O, PtCl₄, PtCl₃, Pt(SO₄)₂.4H₂O and Pt(COCl₂)Cl₂, and corresponding complexes such as NaAuCl₄, (NH₄)₂ PdCl₄ (NH4)₂ PdCl₆, K₂ PdCl₆ and KAuCl₄.

The sublayer obtained is particularly well-suited to electrolytic metallization. For example, electrolytic metallization with an increasing current may be used.

The formation of the sublayer within the context of the first method may especially comprise the following operations:

exposure of the metal oxide particles contained in the first layer of photosensitive resin. This operation is preferably carried out by alkaline etching (for example using a sodium hydroxide or potassium hydroxide solution in aqueous/alcoholic medium) and then rinsing with water, possibly in an ultrasonic bath, so as to remove the oxide particles exposed;

if the first layer of photosensitive resin contains inert fillers, such as calcium carbonate fillers, the surface is made slightly rough by acid etching. This operation is preferably separate from the operation of forming the metal sublayer;

forming a continuous metal sublayer of noble metal by contacting with an aqueous, acid solution of a noble metal salt. By way of indication, it should be mentioned that the sublayer obtained is generally a monoatomic layer since the noble metal acts as a barrier to continuation of the oxidation-reduction reaction. The layer is continuous as some of the metal oxide particles release ions by dissolution. These ions react in aqueous medium with the noble metal salt, reducing this metal, which is deposited, thus filling the inter-particle spaces. The reaction is all the more effective and economic the more confined the aqueous noble metal salt medium. For this reason, it is preferred to carry out the reaction in a thin layer, that is to say by immersion in the solution containing the noble metal salt, and to remove it as soon as possible afterwards. The reaction then takes place in the aqueous solution layer entrained with the object.

According to another method of producing the sublayer, the compound capable of inducing subsequent metallization is chosen from the abovementioned metal oxides and the sublayer is formed by bringing the first layer or exposed parts of the first layer into contact with a reducing agent capable of reducing the oxide particles.

During this step, other layers may be brought into contact with the reducing agent, this having no useful action on them. Thus, a sublayer of reduced and conducting form is formed on the surface of the first layer from the metal oxide.

Within the context of the second method of forming the sublayer, the preferred metal oxide is cuprous oxide Cu₂O. According to this method, the first layer advantageously contains from 10 to 90%, preferably from 25 to 90%, by weight of metal oxide. In an alternative form, it contains less than 10% cuprous oxide. Depending on the case, the sublayer formed is continuous or discontinuous, and has a surface resistivity of between 0.01 and 10⁶ Ω/□.

The surface resistivity that it is possible to achieve in the sublayer depends on the composition of the first layer of photosensitive resin. It should be pointed out by way of indication that the cohesion of the sublayer is better the higher the concentration of oxide particles.

When the first layer of photosensitive resin consists of from 10 to 90% by weight of metal oxide; from 0 to 50% by weight of one or more inert and non-conducting fillers; and from 10 to 90% by weight of polymer resin, the reduction is advantageously continued until a surface resistivity of 0.01 to 10³ Ω/□ is obtained. In general, a continuous sublayer is obtained. The continuity and the surface resistivities reached make it possible in particular to use direct electrolytic metallization on the sublayer. For example, electrolytic metallization with increasing current may be used.

When the first layer of photosensitive resin consists of at least 10% by weight of metal oxide; from 0 to 50% by weight of one or more inert and non-conducting fillers; and from 50 to 90% by weight of polymer resin, the reduction is advantageously continued until a surface resistivity greater than 10⁶ Ω/□ is obtained. In this case, the sublayer may have discontinuities.

The continuous or discontinuous sublayer also allows catalysis of the subsequent metal deposit produced in step g), while still being completely compatible with it.

More specifically, this step helps to improve the adhesion of the subsequent metal deposit, while preventing any break in the electrical conduction within the metallized vias.

The formation of the sublayer within the context of the second method may especially comprise the follows steps:

exposure of the metal oxide particles contained in the first layer of photosensitive resin. This operation is preferably carried out by alkaline etching (for example using a sodium hydroxide or potassium hydroxide solution in aqueous/alcoholic medium) and then rinsing with water, possibly in an ultrasonic bath, so as to remove the oxide particles exposed;

if the first layer of photosensitive resin contains inert fillers, such as calcium carbonate fillers, the surface is made slightly rough by acid etching. This operation is preferably separate from the operation of forming the metal sublayer;

formation of a metal sublayer by contacting with an aqueous solution containing a reducing agent. The sublayer is preferably formed as a thin layer, by immersion in an aqueous solution containing the reducing agent, and immediate removal, according to a principle similar to that described above.

By way of indication, it should be pointed out that when the metal oxide is a cuprous oxide, part of the copper is reduced to the CuH state, in which state the copper acts as a catalyst for the formation of the sublayer. If there is excess CuH, this is slowly converted into copper metal at room temperature, the hydrogen diffusing to the outside. Hereafter, the presence of this transient hydride will not be mentioned further and reference will simply be made to a metal layer.

In order to carry out the reduction, a person skilled in the art may select any one of the reducing agents capable of reducing the metal oxide to metal of oxidation state 0.

Achieving the desired resistivity values during this step will depend, on the one hand, on the proportions and on the nature of the metal oxide contained in the polymer matrix forming the dielectric and, on the other hand, on the extent of the reduction carried out, especially on the type of reducing agent used and the prior stripping step.

The nature of the metal layer deposited varies depending on the type of reducing agent used and on the nature of the metal oxide to be reduced. According to a preferred method of implementing the invention, the reducing agent is a borohydride.

The action of borohydrides when the metal oxide is a cuprous oxide is described more specifically below.

Cu₂O is reduced to metallic copper by the action of a borohydride.

By using this type of reducing agent, the layer formed on the surface of the dielectric is a continuous or discontinuous metal layer of copper.

The borohydrides that can be used include substituted borohydrides as well as unsubstituted borohydrides. Substituted borohydrides in which at most three hydrogen atoms of the borohydride ion have been replaced with substituents which are inert under the reduction conditions, such as for example with alkyl radicals, aryl radicals and alkoxy radicals, may be used. Preferably, alkaline borohydrides are used in which the alkaline part consists of sodium or potassium. Typical examples of compounds that are suitable are: sodium borohydride, potassium borohydride, sodium diethylborohydride and potassium triphenylborohydride.

The reducing treatment is carried out simply by bringing the dielectric surface into contact with a solution of the borohydride in water or in a mixture of water and of an inert polar solvent such as, for example, a lower aliphatic alcohol.

Preference is given to purely borohydride solutions. The concentration of these solutions may vary over wide limits and it preferably lies between 0.05 and 1% (by weight of active hydrogen of the borohydride in the solution). The reducing treatment may be carried out at high temperature; however, it is preferred to do so at a temperature close to room temperature, for example between 15 and 30° C. With regard to the execution of the reaction, it should be noted that it gives rise to B(OH)₃ and to OH⁻ ions, which have the effect of increasing the pH of the medium during the reduction. However, at high pH values, for example greater than 13, the rate of reduction is decreased so that it may be advantageous to operate in a buffered medium so as to have a well-defined reduction rate.

By varying mainly the treatment time, it is possible to easily control the extent of the reduction. To obtain a surface resistivity corresponding to the desired values, the treatment time necessary is generally quite short and, depending on the amounts of oxide included in the dielectric, is usually between about one minute and about fifteen minutes. For a given treatment time, it is possible to further vary the reduction rate by adding various accelerators to the medium, such as for example boric acid, oxalic acid, citric acid, tartaric acid or metal chlorides such as cobalt(II) chloride, nickel(II) chloride, manganese(II) chloride and copper(II) chloride.

It is also possible to vary the amount of borohydride used so as to control the extent of the reduction. A preferred operating method consists in dipping the substrate to be reduced into a relatively viscous borohydride solution and then in withdrawing the substrate in order to allow the reduction operation to take place in air. The amount of borohydride ions BH₄⁻ consumed depends on the viscosity. The BH₄⁻ therefore reacts in a thin layer on the surface to be reduced. This process also has the advantage of neither contaminating the initial bath nor of destabilizing it.

The exact and precise conditions of the reduction by the borohydride are such as those described in EP 82 094. However, it must be understood that, within the context of the invention, only a surface part of the dielectric has to be reduced.

The metallizations on the sublayer are produced as mentioned above.

During the production of the circuitry level, the layer of photosensitive resin is removed. This operation may be carried out in various steps depending on the method of implementation. The removal may be carried out by dissolving or stripping. The techniques of completely removing a layer of photosensitive resin are known.

The removal is easier if the second layer of photosensitive resin is not in an advanced state of cure. Preferably, it is in the A-stage during its removal.

The process may include a treatment step intended to place the first layer of insulating photosensitive resin in an advanced state of cure, for example the B-stage. The treatment may, for example, consist in a curing operation. It is preferably carried out after the second layer of photosensitive resin has been removed. The treatment gives the circuitries greater stability, particularly greater dimensional stability, and thus allows the placement precision of the irradiation and development steps to be improved. In addition, it limits the swelling phenomena in the resins in contact with the solutions used during the various treatments.

The process is particularly suitable for the production of printed circuits and of multilayer modules having a high integration density.

Further details and advantages of the invention will become more clearly apparent in the light of the particular methods of implementation given below. More specifically, three methods of implementation are presented, these being illustrated by figures showing schematic cross-sectional views of the circuitries produced by a process according to the invention at various steps in the process.

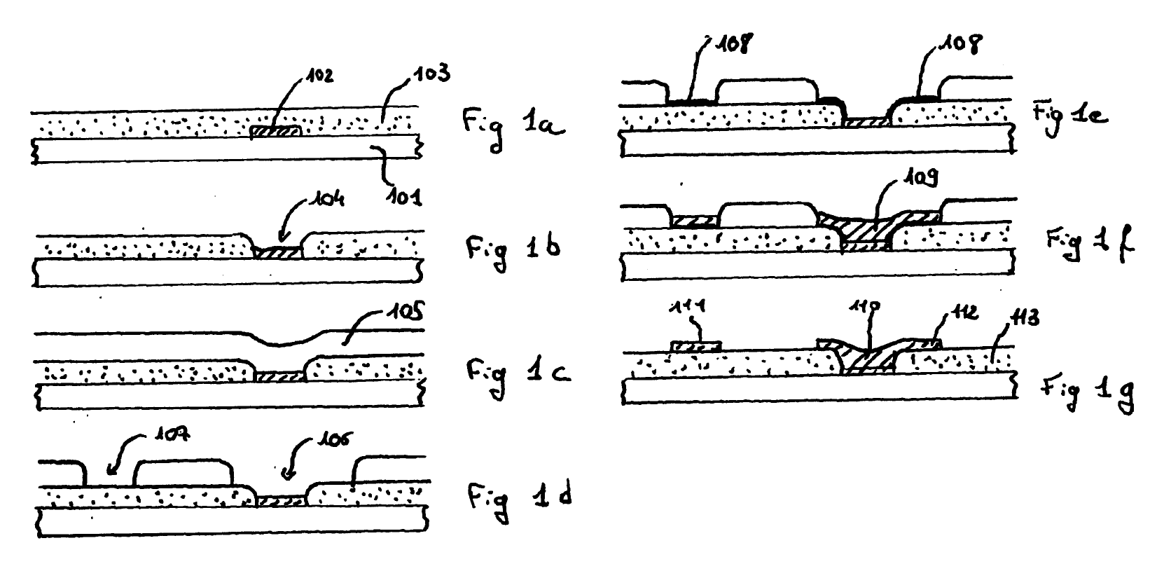

FIGS. 1a) to 1g) represent the circuitry at the various steps in the process according to the first method of implementation.

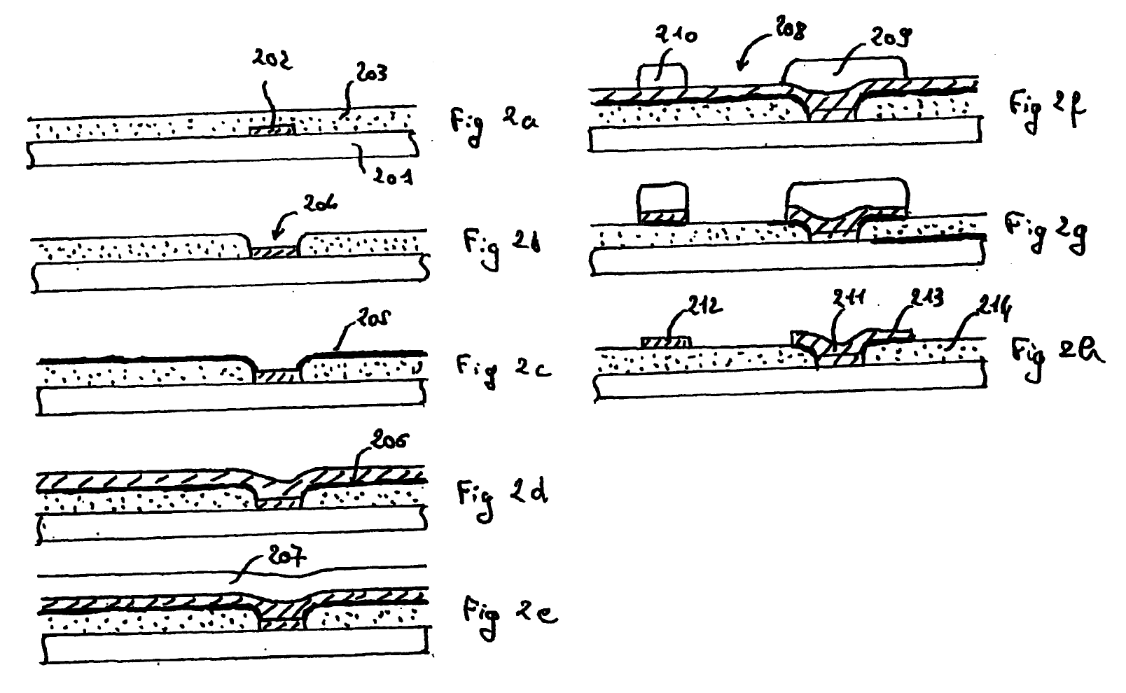

FIGS. 2a) to 2h) represent the circuitry at the various steps in the process according to the second method of implementation.

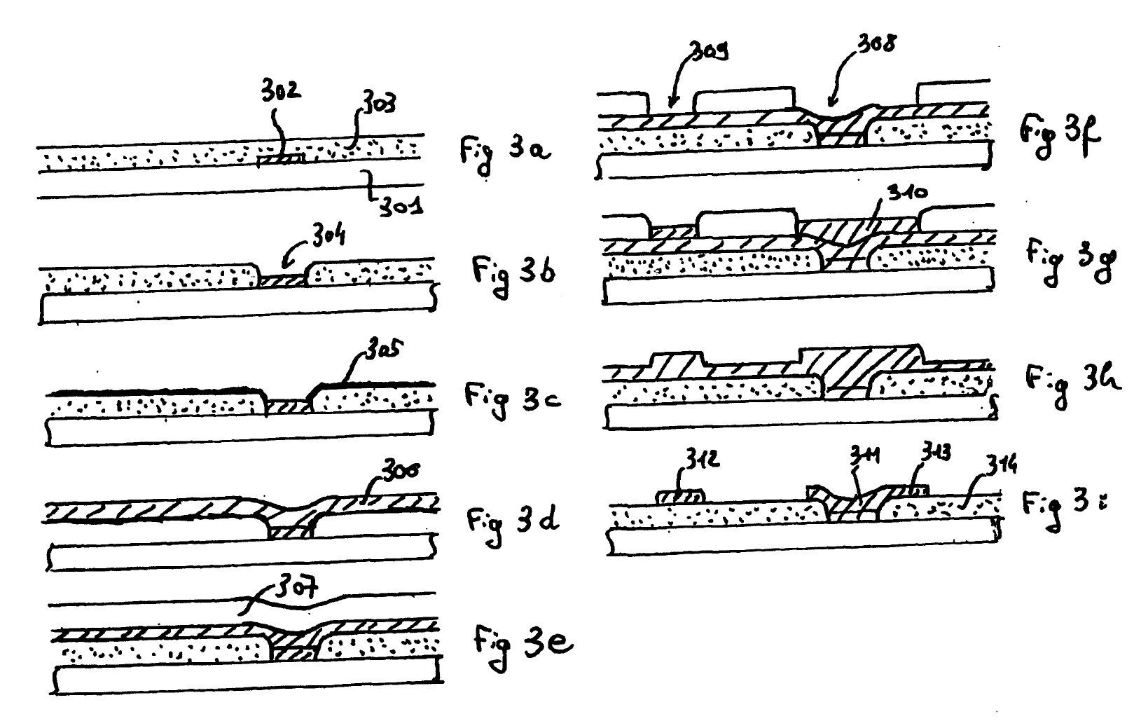

FIGS. 3a) to 3i) represent the circuitry at the various steps in the process according to the third method of implementation.

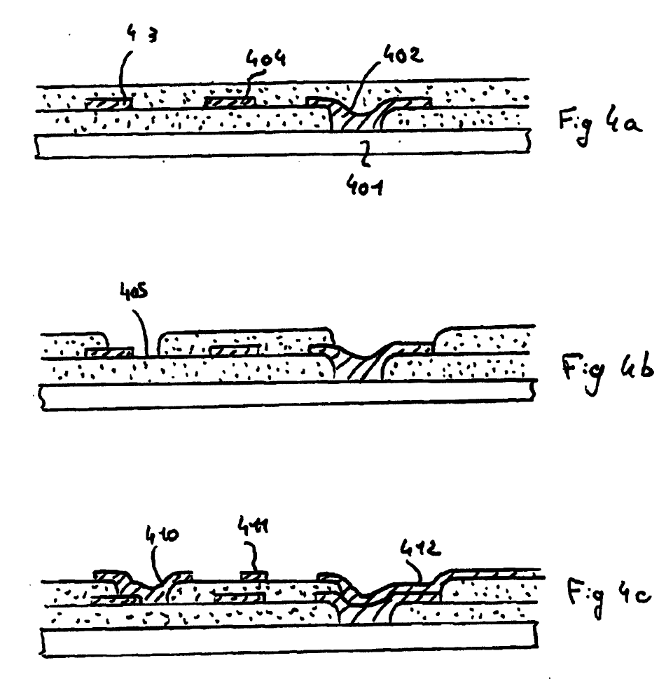

FIGS. 4a) to 4c) represent a multilevel circuitry at various steps in the process.

According to a first method of implementation, the process comprises the following steps:

a1) forming, on a substrate 101 having metallizable parts 102 and/or potentially metallizable parts, a first layer 103 of insulating photosensitive resin containing metal oxide particles, the oxide being chosen from Cu, Co, Cr, Ni, Pb, Sb and Sn oxides and mixtures thereof and, where appropriate, one or more other non-conducting and inert fillers;

b1) irradiating and developing the first layer so as to selectively expose metallizable and/or potentially metallizable parts of the substrate;

c1) forming, on the first layer and on the exposed parts of the substrate, a second layer 105 of photosensitive resin, intended to form selective protection, this second layer not containing metal oxide particles;

d1) irradiating and developing the second layer so as to selectively expose certain parts of the first layer and certain parts of the substrate;

e1) forming a sublayer 107 capable of being metallized either by coming into contact with a solution of a noble metal salt capable of being reduced by the metal oxide particles;

or by coming into contact with a reducing agent capable of reducing the metal oxide particles;

f1) electrochemical and/or electrolytic metallization so as to deposit a metal layer 108 on the exposed parts of the first layer and of the substrate;

g1) removal of the second layer of photosensitive resin.

The first method of implementation corresponds to metallization according to a pattern-type process.

For the first method of implementation, the second layer of photosensitive resin is removed at step g1). Steps a1) and b1) are in accordance with steps a) and b). The compound in the first layer of insulating photosensitive resin capable of inducing subsequent metallization is a metal oxide chosen from Cu, Co, Cr, Ni, Pb and Sn oxides. Step c) of forming tracks and microvias is a sequence of steps comprising step c1), d1), e1), f1) and g1).

The ways of carrying out each step have been detailed above. During the process according to the first method of implementation, a photovia 104, i.e. a via in an insulating photosensitive resin emerging in a metallizable part 102 and/or a potentially metallizable part, is formed in step b1). During step d1), the selective protection is obtained by producing a via 106 in the region of the photovia 104 so as to expose the metallizable part 102 and by producing a via 107 in the region of a part of the first layer of photosensitive resin. During step e1), a sublayer 107 capable of being metallized is formed according to one of the two methods given, preferably the first one, with the aid of noble metal salts in acid medium. In step f1), a metallization is produced, preferably electrolytically. Metal interconnects 109, which will especially form tracks and microvias, are obtained. In step g1), the second layer of photosensitive resin is removed. The surface of the circuitry obtained comprises:

the first layer 113 of photosensitive resin;

parts of tracks 111 on the surface of the first layer, which are not in contact with the substrate;

microvias 110 in contact with the substrate;

parts of the tracks 112 on the surface of the first layer, in contact with the microvia.

According to a second method of implementation, the process comprises the following steps:

a2) forming, on a substrate 201 having metallizable parts 202 and/or potentially metallizable parts, a first layer 203 of insulating photosensitive resin containing metal oxide particles, the oxide being chosen from Cu, Co, Cr, Ni, Pb, Sb and Sn oxides and mixtures thereof and, where appropriate, one or more other non-conducting and inert fillers;

b2) irradiating and developing the first layer so as to selectively expose metallizable and/or potentially metallizable parts of the substrate;

c2) forming a sublayer 205 capable of being metallized on the surface of the first layer of photosensitive resin and of the exposed parts of the substrate;

either by coming into contact with a solution of a noble metal salt capable of being reduced by the metal oxide particles

or by coming into contact with a reducing agent capable of reducing the metal oxide particles;

d2) electrochemical and/or electrolytic metallization so as to deposit a metal layer 206 on the first layer and on the exposed parts of the substrate;

e2) forming on the metallized surface a second layer 207 of photosensitive resin;

f2) irradiating and developing the second layer so as to selectively expose certain parts of the metal layer;

g2) removing the metal layer from the region of the parts exposed during step f2);

h2) removing the second layer of photosensitive resin.

The second method of implementation corresponds to metallization according to a panel-type process.

For the second method of implementation, the second layer of photosensitive resin is removed in step h2). Steps a2) and b2) are in accordance with steps a) and b). The compound in the first layer of insulating photosensitive resin capable of inducing subsequent metallization is a metal oxide chosen from Cu, Co, Cr, Ni, Pb and Sn oxides. Step c) of forming tracks and microvias is a succession of steps comprising steps c2), d2), e2), f2), g2) and h2).

The ways of implementing each step were explained in detail above. During the process according to the second method of implementation, a photovia 204, i.e. a via in an insulating photosensitive resin emerging in a metallizable part 202 and/or a potentially metallizable part, is formed in step b2). During step c2), a layer 205 capable of being metallized is formed over the entire available surface of the first layer, according to one of the two given methods, preferably the first one, with the aid of noble metal salts in acid medium. During step d2), the metallization is carried out in order to obtain a continuous metal layer 206 over the entire available surface. The metallization is preferably carried out electrolytically in acid medium. During step f2), selective protection is obtained by producing vias 208 in the second layer, so that the second layer of photosensitive resin remains present in places on the surface of the metal layer. Thus protection of the second layer 209 in the region of the via 204 and protection of the second layer 210 over a part where there is no via in the first layer thus remain.

In step g2), parts of the metal layer are removed, these parts having been exposed during step f2). This removal may be carried out by etching or by dissolving, using processes known per se. In general, the parts removed are those parts of the metal layer which are not in contact with the parts exposed during step b2) before metallization. Preferably, the removal is carried out by etching, preferably in acid medium.

After the second layer of photosensitive resin has been removed in step h2), the surface of the circuitry obtained comprises:

the first layer 214 of photosensitive resin;

parts of tracks 212 on the surface of the first layer, which are not in contact with the substrate;

microvias 211 in contact with the substrate;

parts of the tracks 213 on the surface of the first layer, in contact with the microvia.

According to a third method of implementation the process comprises the following steps:

a3) forming, on a substrate 301 having metallizable parts 302 and/or potentially metallizable parts, a first layer 303 of insulating photosensitive resin containing metal oxide particles, the oxide being chosen from Cu, Co, Cr, Ni, Pb, Sb and Sn oxides and mixtures thereof and, where appropriate, one or more other non-conducting and inert fillers;

b3) irradiating and developing the first layer so as to selectively expose metallizable and/or potentially metallizable parts of the substrate;

c3) forming a sublayer 305 capable of being metallized on the surface of the first layer of the photosensitive resin and of the exposed parts of the substrate

either by coming into contact with a solution of a noble metal salt capable of being reduced by the metal oxide particles

or by coming into contact with a reducing agent capable of reducing the metal oxide particles;

d3) eventually electrochemical and/or electrolytic metallization so as to deposit a metal layer 306 on the first layer and on the exposed parts of the substrate;

e3) forming a second layer 207 of photosensitive resin on the metallized surface, this second layer not containing metal oxide particles;

f3) irradiating and developing the second layer so as to selectively expose certain parts of the metal layer;

g3) reinforcing the metal layer by metallization in the region of the parts exposed during step f3);

h3) removing the second layer of photosensitive resin so as to expose the metal layer reinforced in certain parts;

i3) etching the metal layer so as to remove all of the layer on the parts which have not been reinforced.

The third method of implementation corresponds to metallization according to a panel-type process with patterned reinforcement.

In the case of the third method of implementation, the second layer of photosensitive resin is removed in step h3). Steps a3) and b3) are in accordance with steps a) and b). The compound in the first layer of insulating photosensitive resin capable of inducing subsequent metallization is a metal oxide chosen from Cu, Co, Cr, Ni, Pb, Sn oxides. Step c) of forming tracks and microvias is a succession of steps comprising steps c3), d3), e3), f3), g3), h3) and i3).

The ways of implementing each step were explained in detail above. During the process according to the third method of implementation, a photovia 304, i.e. a via in an insulating photosensitive resin emerging in a metallizable or potentially metallizable part 302, is formed in step b3). During step c3), a sublayer 305 capable of being metallized is formed over the entire available surface of the first layer, according to one of the two given methods, preferably the first one, with the aid of noble metal salts in acid medium. During a step d3), a metallization may be carried out in order to obtain a continuous metal layer 306 over the entire available surface. By means of step f3), the selective protection is obtained by producing a via 308 so as to expose the metal layer in the region of the photovia 304 and a via 309 is obtained so as to expose the metal layer in the region of part of the first layer where there is no photovia.

In step g3) those parts of the metal layer exposed during step f3), that is to say in the region of the vias 308 and 309, are reinforced. The reinforcement 310 may consist of a simple, easily etchable, metal film, for example of the same nature as the metal layer, and preferably obtained by electrolytic metallization. The thickness of the metal layer on the reinforced parts is greater than on the unreinforced parts. The reinforcement may also consist of a metallic material that is not easily etchable, such as gold.

After the layer of photosensitive resin has been removed in step h3), the metal layer is etched during a step i3) so as to remove all of the metal layer on the parts which have not been reinforced and to leave a metal film on the parts which have been reinforced. This is carried out, for example, by differential etching. The etching is carried out in acid medium, for example.

The surface of the circuitry obtained comprises:

the first layer 314 of photosensitive resin

parts of tracks 312 on the surface of the first layer, which are not in contact with the substrate;

microvias 311 in contact with the substrate;

parts of the tracks 313 on the surface of the first layer, in contact with the microvia.

The circuitry level obtained may support another circuitry level, obtained according to the sequences of similar steps. One embodiment of a second circuitry level is given below, illustrated by FIGS. 4a to 4c.

In this example, the operation is carried out according to a process similar to the first method of implementation.

During a step a4), a first layer of photosensitive resin is formed on the surface of a circuitry level obtained by one of the methods of implementation described above, having the layer 401 of insulating photosensitive resin containing metal oxide particles of the previous circuitry level (the so-called lower level) and having tracks and microvias 402, 403.

During step b4) the first layer of resin is irradiated and developed so as to form photovias 406, 407 emerging in a track or microvia part 402, 403 and, where appropriate, in a potentially metallizable part 405 consisting of part of the first layer of the lower level (the second layer of the lower level was removed).

During step c4) and d4), a second layer of photosensitive resin is deposited, irradiated and exposed so as to form selective protection.

During a step e4), a sublayer capable of being metallized is formed as described above. Furthermore, the sublayer is formed on the unprotected surfaces of the first layer and on the potentially metallizable surface 405.

Metallization is carried out during a step f4). Tracks and microvias 408, 409, 410 are formed.

During a step g4), the second layer of photosensitive resin is removed.

1. Process for fabricating a multilevel interconnect circuitry comprising metal tracks and microvias, comprising the following steps for producing at least one level:
a) forming, on a substrate having metallizable and/or potentially metallizable parts on its surface, a first layer of insulating photosensitive resin containing a compound capable of inducing subsequent metallization;
b) irradiating and developing the first layer so as to selectively expose metallizable and/or potentially metallizable parts of the substrate;
c) forming, by metallization, metal tracks and microvias on the surface of the first layer of insulating photosensitive resin and of the parts exposed in step b), with the use of a second layer of photosensitive resin forming selective protection; characterized in that
the process comprises, for producing the level in question, a step during which the second layer of photosensitive resin is removed.

2. Process according to claim 1, characterized in that the substrate is a lower circuitry level, the metallizable parts being metal tracks or microvias and the potentially metallizable parts being non-metallized parts having the first layer of insulating photosensitive resin for producing a lower level.

3. Process according to claim 1 or 2, characterized in that the second layer of photosensitive resin does not contain a compound capable of inducing subsequent metallization.

4. Process according to one of the preceding claims, characterized in that the compound capable of inducing subsequent metallization consists of particles of a metal oxide chosen from Cu, Co, Cr, Ni, Pb, Sb and Sn oxides and mixtures thereof.

5. Process according to one of the preceding claims, characterized in that the first layer of resin contains inert non-conducting fillers.

6. Process according to one of the preceding claims, characterized in that the metallization is carried out on a sublayer capable of being metallized, formed prior to the surface of the first layer of photosensitive resin or of exposed parts of the first layer of photosensitive resin.

7. Process according to claim 6, characterized in that the compound capable of inducing subsequent metallization consists of particles of a metal oxide chosen from Cu, Co, Cr, Ni, Pb, Sb and Sn oxides and mixtures thereof and in that the sublayer is formed by the first layer of photosensitive resin or parts of the first layer of photosensitive resin coming into contact with a solution of a noble metal salt capable of being reduced by the oxide particles.

8. Process according to claim 7, characterized in that the noble metal salt solution is an acid solution.

9. Process according to either of claims 6 and 7, characterized in that the noble metal salt is chosen from Au, Ag, Rh, Pd, Os, Ir and Pt salts with a counterion chosen from Cl⁻, N0₃⁻ and CH₃COO⁻.

10. Process according to claim 6, characterized in that the compound capable of inducing subsequent metallization consists of particles of a metal oxide chosen from Cu, Co, Cr, Ni, Pb, Sb and Sn oxides and mixtures thereof and in that the sublayer is formed by the first layer of photosensitive resin or parts of the first layer of photosensitive resin coming into contact with a reducing agent capable of reducing the oxide particles.

11. Process according to one of claims 6 to 10, characterized in that the particles in the first layer of photosensitive resin are exposed before the sublayer capable of being metallized is formed.

12. Process according to one of the preceding claims, characterized in that the metallization is carried out electrochemically and/or electrolytically.

13. Process according to one of the preceding claims, characterized in that the metallization is carried out electrolytically in acid medium.

14. Process according to one of claims 7 to 13, characterized in that step c) comprises the following steps:
c1) forming, on the first layer and on the exposed parts of the substrate, a second layer of photosensitive resin, intended to form selective protection, this second layer not containing a compound capable of inducing subsequent metallization;
d1) irradiating and developing the second layer so as to selectively expose certain parts of the first layer and certain parts of the substrate;
e1) forming a sublayer capable of being metallized
either by coming into contact with a solution of a noble metal salt capable of being reduced by the metal oxide particles;
or by coming into contact with a reducing agent capable of reducing the metal oxide particles;
f1) electrochemical and/or electrolytic metallization so as to deposit a metal layer on the exposed parts of the first layer and of the substrate;
g1) removal of the second layer of photosensitive resin.

15. Process according to one of claims 7 to 13, characterized in that step c) comprises the following steps:
c2) forming a sublayer capable of being metallized on the surface of the first layer of the photosensitive resin and of the exposed parts of the substrate
either by coming into contact with a solution of a noble metal salt capable of being reduced by the metal oxide particles
or by coming into contact with a reducing agent capable of reducing the metal oxide particles;
d2) electrochemical and/or electrolytic metallization so as to deposit a metal layer on the first layer and on the exposed parts of the substrate;
e2) forming on the metallized surface a second layer of photosensitive resin intended to form the selective protection;
f2) irradiating and developing the second layer so as to selectively expose certain parts of the metal layer;
g2) removing the metal layer from the parts exposed during step f2);
h2) removing the second layer of photosensitive resin.

16. Process according to one of claims 7 to 13, characterized in that step c) comprises the following steps:
c3) forming a sublayer capable of being metallized on the surface of the first layer of the photosensitive resin and of the exposed parts of the substrate
either by coming into contact with a solution of a noble metal salt capable of being reduced by the metal oxide particles
or by coming into contact with a reducing agent capable of reducing the metal oxide particles;
d3) eventually electrochemical and/or electrolytic metallization so as to deposit a metal layer on the first layer and on the exposed parts of the substrate;
e3) forming on the metallized surface a second layer of photosensitive resin intended to form the selective protection, this second layer not containing a compound capable of inducing subsequent metallization;
f3) irradiating and developing the second layer so as to selectively expose certain parts of the metal layer;
g3) reinforcing the metal layer by metallization in the region of the parts exposed during step f3);
h3) removing the second layer of photosensitive resin so as to expose the metal layer reinforced in certain parts;
i3) etching the metal layer so as to remove all of the layer on the parts which have not been reinforced.

17. Process according to one of the preceding claims, characterized in that it includes a step of treating the first layer of photosensitive resin so as to obtain a B-stage resin.

18. Process according to claim 17, characterized in that the treatment step is a curing step carried out after the second layer of photosensitive resin has been removed.

19. Process according to one of the preceding claims, characterized in that the substrate is a rigid printed circuit comprising tracks on its surface.

20. Use of a process according to one of the preceding claims for producing printed circuits and multilayer modules having a high integration density.

21. Circuitries comprising tracks and microvias capable of being obtained by a process according to one of claims 1 to 19.
